(19) United States
(12) Patent Application Publication
(10) Pub. No.: US 2025/0118677 A1
(43) Pub. Date: Apr. 10, 2025

(54) SYSTEM AND METHODS FOR A MULTI-STACK ARCHITECTURE

(71) Applicant: Samsung Electronics Co., Ltd., Suwon-si (KR)

(72) Inventors: Jin YANG, San Jose, CA (US); WooPoung KIM, San Jose, CA (US); Ramkumar SUBRAMANIAN, San Jose, CA (US); Sriram BALASUBRAMANIAN, Fremont, CA (US); Martin Philip SCOTT, San Francisco, CA (US)

(21) Appl. No.: 18/791,420

(22) Filed: Jul. 31, 2024

Related U.S. Application Data
(60) Provisional application No. 63/543,507, filed on Oct. 10, 2023.

(51) Int. Cl. H01L 23/538; H01L 21/56; H01L 21/683; H01L 23/00; H01L 23/48; H01L 25/065; H01L 25/18; H10B 80/00

(52) U.S. Cl. CPC H01L 23/5386; H01L 21/568; H01L 21/6835; H01L 25/0652; H01L 25/0655; H01L 25/18; H01L 23/481; H01L 24/08; H01L 24/80; H01L 2224/08145; H01L 2224/80895; H01L 2224/80896; H01L 2924/1431; H01L 2924/1436; H10B 80/00

(57) ABSTRACT

A method, system and devices are disclosed providing a first layer, the first layer including a first device region and a second device region, and a second layer including an interconnection die, the interconnection die including an interface logic. The first device region and the second device region are mounted on a first side of the interconnection die, and the first device region and the second device region are communicatively coupled to the interface logic.

### CROSS-REFERENCE TO RELATED APPLICATION

This application claims the priority benefit under 35 U.S.C. § 119(e) of U.S. Provisional Application No. 63/543,507 filed on Oct. 10, 2023, the disclosure of which is incorporated herein by reference in its entirety.

### TECHNICAL FIELD

The subject matter disclosed herein relates to microelectronics packaging and integrated circuits (IC) packaging. More particularly, the subject matter disclosed herein relates to a package architecture using a multi-stack architecture.

### BACKGROUND

Semiconductor devices may connect to additional devices and circuitry on different substrates. Forming connections between substrates can provide increased computation by allowing different computational components to operate in concert. However, forming connections between substrates can cause complications. Packaging describes the general method for connecting and integrating multiple computational components together in an integrated unit, and may involve multiple different types of integrated circuits on multiple substrates which may combine into a single unit. Packaging may also describe the method for which multiple computational components within a single unit are protected by the use of various techniques to provide thermal, physical and electrical protection. Such protection may provide only a limited number of external connections for the protected computational components. Background concepts discussed herein are for informational purposes only and are not intended to limit the present disclosure. Nor should the background or field described herein be intended to limit the disclosure herein to a particular use or concept

### SUMMARY

An example embodiment provides a device including a first layer, the first layer including a first device region and a second device region. The device includes a second layer, the second layer including an interconnection die, the interconnection die including an interface logic. The first device region and the second device region are mounted on a first side of the interconnection die, and the first device region and the second device region are communicatively coupled to the interface logic.

In some embodiments, the first device region includes at least one component device including at least one of a memory device and a processing device, and the second device region includes at least one component device including at least one of a memory device and a processing device. The first device region may include a first device and a second device, the first device including at least one of a memory device and a processing device, and the second device including at least one of a memory device and a processing device. In some embodiments, the first device region and the second device region may have the same device composition. In some embodiments, the first device region and the second device region may have a different device composition. In some embodiments, the interface logic may include a serial interface logic or a parallel interface logic. In some embodiments, the interface logic may be between the first device region and the second device region. In some embodiments, the interconnection die has an interconnection region on a second side of the interconnection die, the second side of the interconnection die opposite the first side of the interconnection die. The interconnection region may be formed from at least one of pillars, bumps, and pads. The interconnection region may be communicatively coupled with the first device region and the second device region. In some embodiments, the interface logic may include a serial interface logic or a parallel interface logic, and the interface logic may be mounted on a first side of the first device region and the second device region is mounted on a second side of the first device region, opposite the first side.

An example embodiment provides a system including a first layer and a second layer, with the second layer on top of the first layer. The first layer may include a first device stack and a second device stack. The first device stack is formed in a first device region and the second device stack is formed in a second device region. The second layer may include an interconnection die and an interface logic. The first device stack may be connected by a first through via, the second device stack may be connected by a second though via, and both the first though via and the second through via are communicatively coupled to the interface logic. In some embodiments, the first device stack and the second device stack have the same device composition. In some embodiments, the first device stack and the second device stack have different device compositions. In some embodiments, the interface logic is a parallel logic, and is arranged on a first side of the first device stack, with the second device stack arranged on a second side of the first device stack, opposite the first side.

An example embodiment provides a method including forming an interconnection die, the interconnection die including an embedded interface logic, and forming a wiring layer communicatively coupled to the embedded interface logic. A first device and a second device may be mounted on the interconnection die, with the first device and the second device communicatively coupled to the wiring layer. Additional first devices may be mounted on the first device to form a first device region, with the additional first devices communicatively coupled to the first device. Additional second devices may be mounted on the second device to form a second device region, with the additional second devices communicatively coupled to the second device. A molding layer may be formed over the interconnection die, the first device region, and the second device region. In some embodiments, the first device region and the second device region may have the same device composition. In some embodiments, the first device region and the second device region may have a different device composition. In some embodiments, mounting the first device and the second device on the interconnection die includes mounting the first device on a first side of the embedded interface logic, and mounting the second device on a second side of the embedded interface logic, the second side opposite the first side. In some embodiments, mounting the first device and the second device on the interconnection die includes mounting the second device on a first side of the first device, and mounting the embedded interface logic on a second side of the first device, the second side opposite the first side.

### BRIEF DESCRIPTION OF THE DRAWING

In the following section, the aspects of the subject matter disclosed herein will be described with reference to exemplary embodiments illustrated in the figures, in which:

FIG. 1 depicts a perspective view of an example embodiment of a packaging structure according to various embodiments of the subject matter disclosed herein;

FIG. 2 depicts a cross-section view of an example embodiment of a packaging structure according to various embodiments of the subject matter disclosed herein;

FIG. 3 depicts a plan view of an example embodiment of a packaging structure according to various embodiments of the subject matter disclosed herein;

FIG. 4 depicts a cross-section view of an example embodiment of a packaging structure according to various embodiments of the subject matter disclosed herein;

FIG. 5 depicts a cross-section view of an example embodiment of a packaging structure according to various embodiments of the subject matter disclosed herein;

FIG. 6A depicts a cross-section view of an example embodiment of a packaging structure assembly at a first time according to various embodiments of the subject matter disclosed herein;

FIG. 6B depicts a cross-section view of an example embodiment of a packaging structure assembly at a second time according to various embodiments of the subject matter disclosed herein;

FIG. 6C depicts a cross-section view of an example embodiment of a packaging structure assembly at a third time according to various embodiments of the subject matter disclosed herein;

FIG. 6D depicts a cross-section view of an example embodiment of a packaging structure assembly at a fourth time according to various embodiments of the subject matter disclosed herein;

FIG. 6E depicts a cross-section view of an example embodiment of a packaging structure assembly at a fifth time according to various embodiments of the subject matter disclosed herein;

FIG. 7 depicts an example embodiment of a method of forming a package structure according to various embodiments of the subject matter disclosed herein;

FIG. 8 depicts a cross-section view of an example embodiment of a packaging structure according to various embodiments of the subject matter disclosed herein;

FIG. 9 depicts a plan view of an example embodiment of a packaging structure according to various embodiments of the subject matter disclosed herein;

FIG. 10 depicts a plan view of an example embodiment of a packaging structure according to various embodiments of the subject matter disclosed herein; and

FIG. 11 depicts a plan view of an example embodiment of a packaging structure according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clockwise,” “Three-Dimensional,” etc.) may be interchangeably used with a corresponding non-capitalized version (e.g., “counter clockwise,” “three-dimensional,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination. Bonding substrates may be thus known in some embodiments as die-to-die (D2D) bonding, wafer-to-wafer bonding (W2W) or die-to-wafer bonding (D2W). In some embodiments, the substrates may contain circuits such as integrated circuits including central processing units (CPUs), logic chips, memory such as static random-access memory (SRAM), dynamic random-access memory (DRAM), synchronous dynamic random-access memory (SDRAM), double data rate DRAM or DDR DRAM, application processors (AP), graphical processing units (GPUs), other forms of auxiliary processing units (xPU), Artificial intelligence (AI) chips, High bandwidth memory (HBM) interfaces, and other application-specific integrated circuits (ASIC). In some embodiments, a combination of circuits may be present on a substrate. In some embodiments, a substrate may include a packaged chip.

As used herein, high bandwidth memory or HBM, may refer to a chip structure including one or more HBM modules. In some embodiments, the HBM may be manufactured by an advance silicon node process.

As used herein packaging refers to a process of forming interconnections between substrates. In some embodiments, the interconnections may be between direct surfaces and involve W2W, D2D, and D2W bonding. In other embodiments, techniques including wire bonding and other forms of indirect bonding may be performed alone or in combination with W2W, D2D, and D2W bonding. In some embodiments, circuits may be bonded directly facing each other, while in other embodiments a flip-chip bonding may be used. In some embodiments, interconnections may be made between substrates on a front or circuit side of the substrate. In other embodiments, interconnections may be made on a rear or back side of the substrate opposite from the circuit structure. In some embodiments, an interconnection may include through-silicon vias (TSVs) or other forms of through-chip vias where one or more substrates may be connected using a via traveling through an interposer such as another substrate or chip. In some embodiments, an interconnection may be formed using connections on a surface of a substrate, such as a pad, and may use additional materials between the pads such as solder to form an interconnection.

As used herein, conductors may refer to a variety of conductive materials, including which materials may be used alone or in combination with other materials such as in the form of an alloy. In some embodiments the conductor is copper (Cu). In some embodiments, copper (Cu) may be in the form of Cu (II), Cu (III) or other forms of copper, alone or in combination with additional elements, including cobalt (Co) and Ruthenium (Ru). Such a listing of elements is not intended to be exhaustive, and in other embodiments, any known other type of conductive material may be used.

Disclosed herein are various embodiments of devices, systems and methods related to packaging architecture to modularly create a stack logic and memory building block architecture using various forms of bonding, including hybrid bonding. As used herein, hybrid bonding may be defined as bonding both conductive portions to conductive portions, and dielectric portions to dielectric portions.

Disclosed herein are various embodiments of devices, systems, and methods related to systems and methods related to packaging architecture to modularly create a stack logic and memory building block architecture using a shared die to stack multiple devices thereupon. A stack logic and memory building block architecture may include a base die providing logic, routing, and power delivery to one or more stacks of memory and compute elements. As used herein, a device stack or stack of devices may refer to a combination of memory, compute, and supporting circuit architecture, for example, chiplets and dies containing individual memory elements, processing units, input output (I/O) circuitry, and other forms of integrated chips.

A stack logic and memory building block architecture using a shared die may provide an integrated unit allowing multiple different compute devices to be placed together for a high density of computation and memory. Multiple devices, such as chiplets and dies may be stacked together to create an HBM module providing high-bandwidth memory for uses in fields like HPC and AI. The stack of devices may then be integrated into a larger system, such as a system-on-a-chip (SOC) and provide additional compute resources to increase performance. Such larger systems may face complications as additional stacks of devices are added, as central compute devices for such larger systems have space limitations to add interconnections. Various embodiments of the stack logic and memory building block architecture disclosed herein may allow multiple device stacks to integrated upon a shared interconnection die. The shared interconnection die may provide a connection for multiple device stacks to communicate to a central compute device. In some embodiments, the shared interconnection die may include logic to provide a D2D connection between multiple device stacks and additional compute resources upon another die.

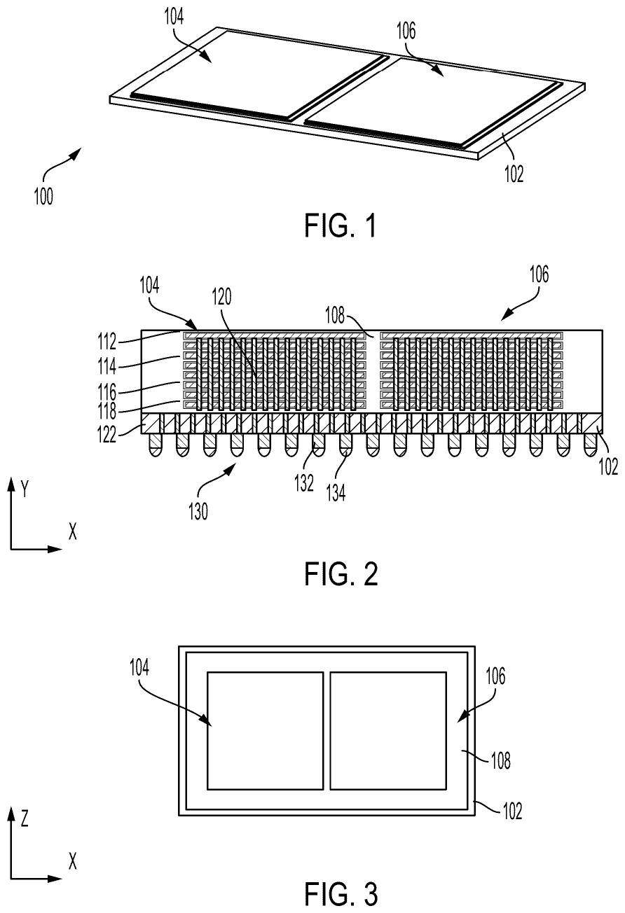

FIG. 1 depicts an exemplary embodiment of a device package 100 from a perspective view. An interconnection die 102 supports a first device region 104 and a second device region 106 (also referred to herein generically as a “device” and collectively as “devices”). In some embodiments, the devices may include a processor die, or a processor chiplet. In some embodiments, the devices may be various forms of memory including DRAM, SRAM, and other forms of memory. In some embodiments, the devices may include a core device, for example a processor or other form of microcontroller to act as a controller. In some embodiments, the first device region 104 and the second device region 106 may each comprise a stack of one or more component devices.

In some embodiments, the interconnection die 102 may be a silicon die, while in other embodiments a variety of semiconductor materials may be used, either alone or in combination. For example, in some embodiments, the interconnection die 102 may comprise a SOI substrate such as glass, as well as a germanium, sapphire or other form of semiconductor, either alone, in combination with another semiconductor, or with an insulator such as glass.

The interconnection die 102 may also be referred to as the base die, the buffer die, the interconnection die, and the supportive interconnection. In some embodiments, the interconnection die 102 may function as the buffer of a HBM stack of dies. The interconnection die 102 may have high speed interconnections such as physical layer (PHY) interconnections, D2D interconnections, and fine pitch microbumps, as well as any other suitable form of interconnection. In some embodiments, the interconnection die 102 may include one or more test logics for use in testing various devices within the device package 100. For example, in some embodiments, the interconnection die 102 may include one or more of a DRAM core die's cell level testing circuits, I/O testing circuits, and loopback testing circuits. In some embodiments, one or more test logics may be usable with the first device region 104, the second device region 106, or a combination thereof. In some embodiments, the one or more test logics may usable with devices external to the device package 100, while in some embodiments the one or more test logics may be utilized within the device package 100.

FIG. 2 depicts another view of the device package 100, showing the device package 100 as shown in FIG. 1 in a cross-sectional view. As shown in FIG. 2, the first device region 104 has a plurality of component devices including a first layer device 112, a second layer device 114, a third layer device 116 and a fourth layer device 118 stacked vertically, with the first layer device 112 on top of the second layer device 114, the second layer device 114 on top of the third layer device 116, the third layer device 116 on top of the fourth layer device 118, the fourth layer device 118 on top of the interconnection die 102. In some embodiments, the stack of component devices may include memory devices, core devices, processing devices, and combinations thereof. The first device region 104 and the second device region 106 may, in some embodiments, include the same component devices, while in other embodiments the component devices in the first device region 104 and the second device region 106 may differ. In some embodiments, a through-via 120 may electrically connect the individual devices within a device region to each other and to the interconnection die 102.

The number of component devices within the first device region 104 or second device region 106 may vary, and the number of component devices and type of component devices provided may vary based on the relative amount of computing desired for each device. For example, a desired ratio between core dies and memory dies may be desired, for example 1 core per 4 memory dies may be desired in some embodiments. However, in other embodiments, the ratio may vary, for example, and in some embodiments the ratio may be greater and include 1 core per 5, 6, 10, or even 16 memory die. The number and nature of the devices may be referred to as the device composition.

FIG. 3 depicts an additional view of the device package 100, with FIG. 3 depicting a plan view of the device package 100, in comparison to the cross-sectional view of FIG. 2 and the perspective view of FIG. 1. As shown in the exemplary embodiments of FIGS. 2 and 3, a molding layer 108, such as a dielectric material or an adhesive layer such as a resin or epoxy, may be provided between the first device region 104, the second device region 106 and interconnection die 102. In some embodiments, dielectric material such as silicon nitride (Si₃N₄) or silicon dioxide (SiO₂) may be used to form the molding layer 108. In some embodiments, the first device region 104 and the second device region 106 may be encapsulated by the molding layer 108, and may include additional encapsulations layers upon the sides or top of the first device region 104 and the second device region 106. The encapsulation layers may be a dielectric material or an adhesive layer such as resin or epoxy. In some embodiments, the molding layer 108 may provide mechanical support, such as holding the devices in places, as well as may provide electrical isolation, and may provide a thermal path for heat from the devices to transfer via. In some embodiments, the molding layer 108 may cover the first layer device 112, while in other embodiments, the molding layer 108 may not cover the first layer device 112 such that the first layer device 112 has a top surface exposed.

In the device package 100, the first device region 104 and the second device region 106 may be electrically coupled to one or more wiring layers 122 within the interconnection die 102 via the through-via 120. The one or more wiring layers 122 within the interconnection die 102 may, in turn, electrically couple the first device region 104 and the second device region 106 to an additional interposer or substrate using interconnections 130 on a bottom side of the interconnection die 102 opposite a top side of the interconnection die 102 holding the first device region 104 and the second device region 106. The interconnections 130 on the bottom side of the interconnection die 102 may include one or more pillars 132 and one or more bumps 134. In some embodiments, the one or more pillars 132 may be formed of copper, or any other suitable conductive material. In some embodiments, the one or more bumps 134 may include microbumps, balls, and other forms such as controlled-collapse chip connection (C4) bumps alone or in combination. In some embodiments, the one or more bumps 134 may be formed on the one or more pillars 132, while in some embodiments the one or more bumps 134 may be used alone or in combination with the one or more pillars 132 within the same plane. In some embodiments, an interposer may include one or more redistribution layers allowing the first device region 104 and the second device region 106 to electrically couple to one or more compute devices via the one or more bumps 134 and the one or more pillars 132. In addition, the interconnections 130 may provide mechanical support for the device package 100 to be mounted on an interposer or substrate.

Although referred to as wiring layers 122, one or more of the wiring layers 122 may take the form of series of pads, bumps, vias, through-vias, traces, redistribution layers and other forms of connection for redistributing signals in various combinations. Similarly, the redistribution layers may also take the form of series of pads, bumps, vias, through-vias, traces, redistribution layers and other forms of connection for redistributing signals in various combinations.

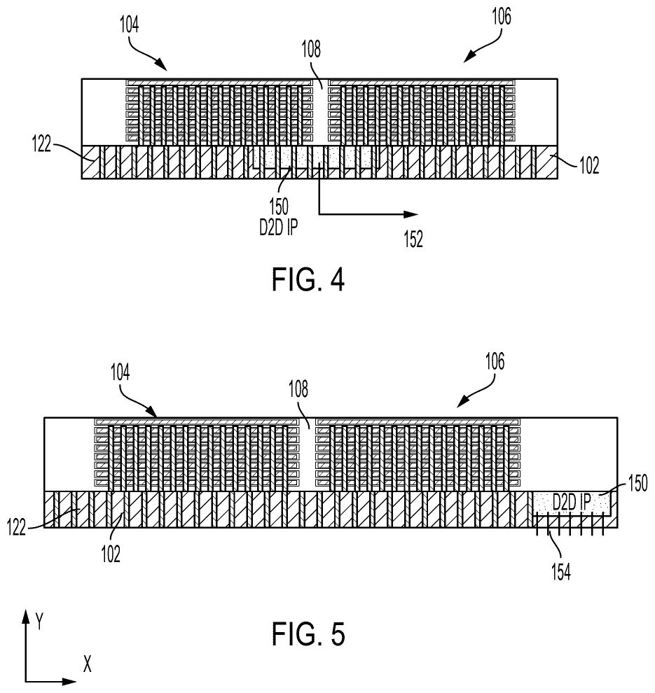

In some embodiments, the interconnection die 102 may include one or more elements embedded therein interconnection die 102. In some embodiments, an interconnection may be embedded within the interconnection die 102. FIG. 4 depicts an example embodiment with an interface logic 150 embedded within the interconnection die 102.

In some embodiments, the interface logic 150 may be a D2D internet protocol or D2D IP logic. In some embodiments, the interface logic 150 may be an interface logic within the interconnection die 102. In some embodiments, the interface logic 150 may be on a surface of the interconnection die 102. In some embodiments, the interface logic 150 may be distributed across the logic of the interconnection die 102 and may be present on one or more layers across or within the interconnection die 102. In other embodiments, the interface logic 150 may be present in a single location on the interconnection die 102, in one or more layers. In some embodiments, the interface logic 150 may take the form of a chiplet, which may be embedded within the interconnection die 102.

In the exemplary embodiment of FIG. 4, the interface logic 150 may be placed between the first device region 104 and the second device region 106 within the interconnection die 102. The interface logic 150 may electrically connect with the one or more wiring layers 122 to electrically connect the first device region 104 and the second device region 106 to external devices such as an interposer or substrate. In other embodiments, such as the exemplary embodiment of FIG. 5, the interface logic 150 may be placed at the edge of the interconnection die 102, and may in some embodiments not be directly under either the first device region 104 or the second device region 106, while in other embodiments, the interface logic 150 may be under a single device of either the first device region 104 or the second device region 106. In some embodiments, the interface logic 150 may be distributed across the logic of the interconnection die 102 and may be present on one or more layers. In other embodiments, the interface logic 150 may be present in a single location on the interconnection die 102, in one or more layers.

In some embodiments, the placement of the device may be related to the protocol used by the interface logic 150, and whether a serial or parallel protocol is used by the interface logic 150. For example, in the exemplary embodiment of FIG. 4, a Serializer/Deserializer (SerDes) protocol may be used to provide a SerDes connection 152 using a SerDes D2D IP. In some embodiments, other serial protocols may be used alone or in combination with a SerDes protocol. In contrast, in the exemplary embodiment of FIG. 5, the Universal Chiplet Interconnect Express (UCIe) protocol may be used to provide a parallel connection 154. In some embodiments, other parallel protocols may be used alone or in combination with the UCIe protocol. In some embodiments, a serial protocol may be used with the interface logic 150 directly under the first device region 104 and the second device region 106. In some embodiments, a parallel protocol may be used with the interface logic 150 placed at the edge of the interconnection die 102. Of course, in other embodiments, a parallel protocol may be used with the interface logic 150 directly under the first device region 104 and the second device region 106; and a serial protocol may be used with the interface logic 150 placed at the edge of the interconnection die 102. In some embodiments, the interface logic 150 may be oriented along an edge of the device package 100. In some embodiments, the placement of the interface logic 150 oriented along a side the device package 100 may allow for a more direct connection to additional dies, and may provide a reduction in routing distances, as well as a decrease in latency and an increase in performance for the device package 100 as a whole.

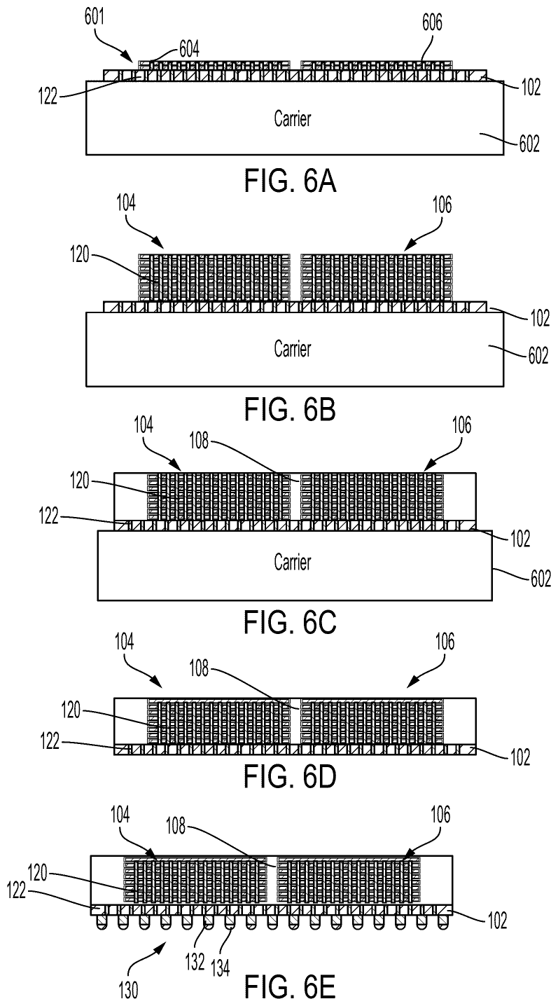

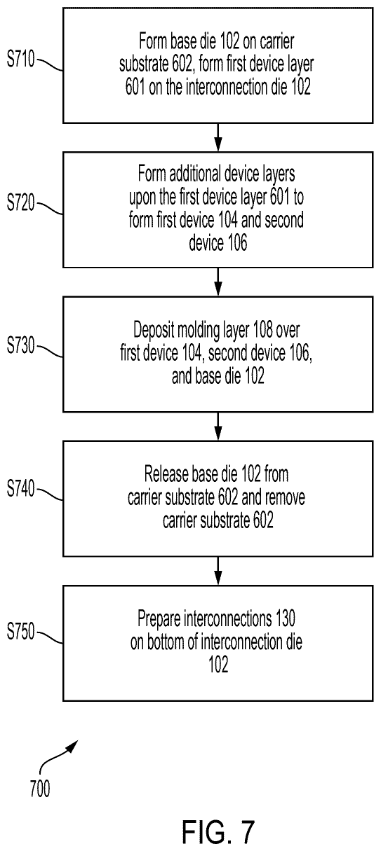

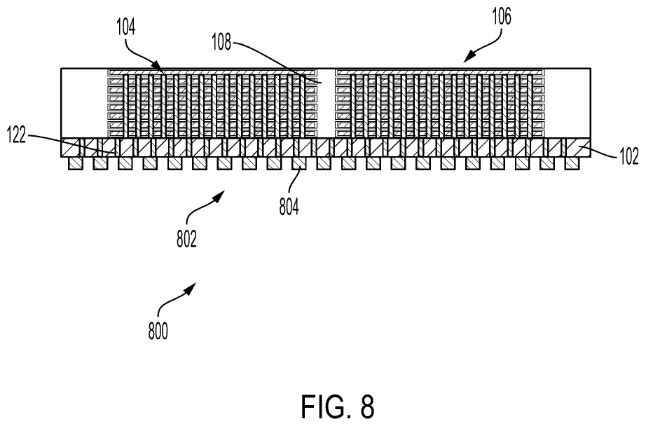

FIGS. 6A-6E depict an illustrative embodiment of a process of forming a device package structure such as the device package 100, or any other device package structures shown herein. FIG. 7 depicts an example embodiment of a process 700 for forming a device package assembly corresponding to the illustrative embodiment of FIGS. 8A-8E.

FIG. 6A shows at S710 in FIG. 7 where a first device layer 601 on the interconnection die 102 is formed on a carrier substrate 602. The carrier substrate 602 may be any suitable substrate, such as a glass substrate. In some embodiments, prior to the interconnection die 102 being formed on the carrier substrate 602, a release layer may be formed on the carrier substrate 602. The release layer may comprise a material such as a polymer, wax, epoxy, or resin which acts as a sacrificial layer and may be cleanly removed from the carrier substrate 602 and the interconnection die 102. In some embodiments, the interconnection die 102 may be formed using complementary metal-oxide-semiconductor (CMOS) processes, such as depositing, lithography, etching, passivation directly on the carrier substrate 602. In some embodiments, the interconnection die 102 may be formed on a separate substrate and transferred to the carrier substrate 602. The interface logic 150 may be formed as part of the interconnection die 102, or may be formed separately and transferred to the interconnection die 102.

On top of the interconnection die 102, the first device layer 601 is formed by mounting a first base device 604 and a second base device 606 on the interconnection die 102. The first base device 604 and the second base device 606 may be either a core device or a memory device. The devices in the first device layer 601 may be mounted directly on the interconnection die 102 and connected to the one or more wiring layers 122. In some embodiments, the first device layer 601 may be bonded directly to the one or more wiring layers 122. In some embodiments, the first device layer 601 may be bonded indirectly to the one or more wiring layers 122, for example by using one or more intermediate layers. In some embodiments, the first device layer 601 and the interconnection die 102 may include metallic materials and dielectric materials including surfaces of the dielectric and metallic materials. For example, the first base device 604 and the second base device 606 may include conductive interconnections for forming the through-via 120. The conductive interconnections may take the form of a metallic interconnection surrounded by a dielectric material, with both dielectric and metallic materials present on the surface of the first device layer 601. In some embodiments, a metallic bond may be utilized between the first device layer 601 and the interconnection die 102, a dielectric bond may be utilized between the first device layer 801 and the interconnection die 102, or in some embodiments a hybrid bond may be utilized between the first device layer 601 and the interconnection die 102. In some embodiments, a heat treatment or other thermal process may be provided to form or strengthen a bond between the first device layer 801 and the interconnection die 102.

FIG. 6B shows at S720 in FIG. 7 where the first device region 104 and the second device region 106 are formed by stacking additional device layers upon the first device layer 801. The additional device layers may be stacked on the first device layer 601 similarly to the first device layer 601 on the interconnection die 102. The additional device layers may be aligned so that the through-via 120 is formed within each stack. Additional heat treatments or thermal processes may be provided to form or strengthen the bonds between each layer.

FIG. 6C shows at S730 in FIG. 7 where the molding layer 108 is deposited over the first device region 104, the second device region 106 and the interconnection die 102. The molding layer 108 may be deposited to provide electrical separation between the first device region 104, the second device region 106 and the interconnection die 102, as well as providing mechanical support for the stacked devices. After forming the molding layer 108, the surface of the molding layer 108, the first device region 104 and the second device region 106 may be subject to a process to smooth and or planarize the surface, the process including one or more grinding, polishing, and smoothing processes, including chemical mechanical planarization (CMP). In some embodiments, the process may expose the top surfaces of the first device region 104 and the second device region 106. In other embodiments, the top surfaces of one or more of the first device region 104 and the second device region 106 may remain covered by the molding layer 108.

FIG. 6D shows at S740 in FIG. 7 the first device region 104 and second device region 106 mounted upon the interconnection die 102 are released from the carrier substrate 602. The carrier substrate 602 may be released, for example, by using one or more of layer release, chemical release, thermal release, or photo release techniques to release an adhesive layer coupling the carrier substrate 602 to the interconnection die 102. For example, in some embodiments a chemical release technique may use a solvent to dissolve the adhesive directly, while a thermal release technique may apply heat to the carrier wafer to melt the adhesive, and a photo release technique may use lasers to directly apply energy to the adhesive layer to reduce the adhesive strength.

FIG. 6E shows at S950 in FIG. 7 where the interconnections 130 may be formed on the bottom of the interconnection die 102. The interconnections 130 may include pads, bumps, microbumps, pillars, balls, and other forms such as C4 bumps, alone or in combination. In some embodiments, a dielectric material or adhesive material, including underfill may also be included. In the example embodiment of FIG. 6E, the interconnections 130 include the one or more pillars 132 which are formed on the bottom of the interconnection die 102, and the one or more bumps 134 which are formed on the one or more pillars 132.

FIG. 8 depicts an example embodiment of a device packaging structure 800. The device packaging structure 800 of FIG. 8 differs from the device package 100 of FIGS. 1-3 in that pillar interconnections 802 are used instead of the interconnections 130. The pillar interconnections 802 includes pillars 804 coupled to the bottom of the interconnection die 102. In some embodiments, the pillar interconnections 802 may include one or more pads. The pillars 804 and one or more of the pads may be formed from copper or any other suitable conductive material. In some embodiments, the pillar interconnections 802 may be assembled onto a package using metallic bonding, diffusion bonding, or hybrid bonding.

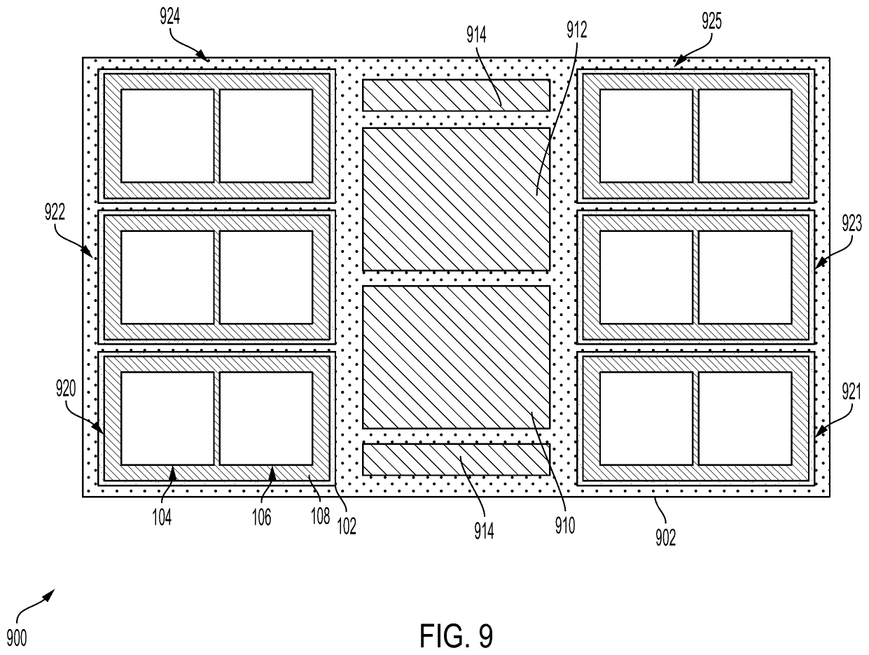

FIG. 9 depicts an exemplary embodiment of a first packaging structure 900 incorporating the device packages disclosed herein,. For example, in some embodiments, one or more of the device package 100 may be mounted within a larger package including one or more compute devices, one or more I/O devices such as a connectivity chiplet 914, a supporting substrate 902, and one or more embedded bridges. The first packaging structure 900 may allow for one or more of the device package 100 to communicatively couple with the one or more compute devices to provide computational resources such as memory and processing.

The one or more compute devices may include a first compute device 910, a second compute device 912, and a third compute device 916. In some embodiments, the compute devices may include a processor die, or a processor chiplet. In some embodiments, a single compute device may be used, while in other embodiments, additional compute devices may be added, for example 4, 6, 8, 16 or 32 compute devices may be added. In some embodiments, the first compute device 910 and the second compute device 912 may share a support die, while in other embodiments, each compute device may have a separate support die. In some embodiments, the support die may be a silicon die, while in other embodiments a variety of semiconductor materials may be used. In some embodiments, the compute devices may include a processor die, or a processor chiplet.

A plurality of device packages may be present in the first packaging structure 900. The plurality of device packages may include the device package 100. In the exemplary embodiments of FIG. 9, a first device package 920, a third device package 922, and a fifth device package 924 may be on one side of the compute devices, while a second device package 921, a fourth device package 923, and a sixth device package 925 may be on the opposing side.

The connectivity chiplet 914 may contain I/O circuitry to allow the first packaging structure 900 to connect to additional devices. For example, in some embodiments, the connectivity chiplet 914 may provide wireless connections, using one or more form of radiofrequency protocol for one or more frequency spectrums. In some embodiments, the connectivity chiplet 914 may provide for optical communication or wired communications, alone or in some combination with wireless communications.

FIG. 9 depicts an exemplary embodiment of the first packaging structure 900 using the supporting substrate 902. In some embodiments, the supporting substrate 9902 may be an organic substrate such as a polymer, while in other embodiments an inorganic substrate such as a semiconductor including silicon may be used, or alternatively a SOI substrate such as glass. In some embodiments, the supporting substrate 902 may be multiple substrates, and in some embodiments may be multiple substrates stacked upon each other. In FIG. 9, the plurality of device packages may connect via the supporting substrate 902 to the one or more compute devices and the connectivity chiplet 914.

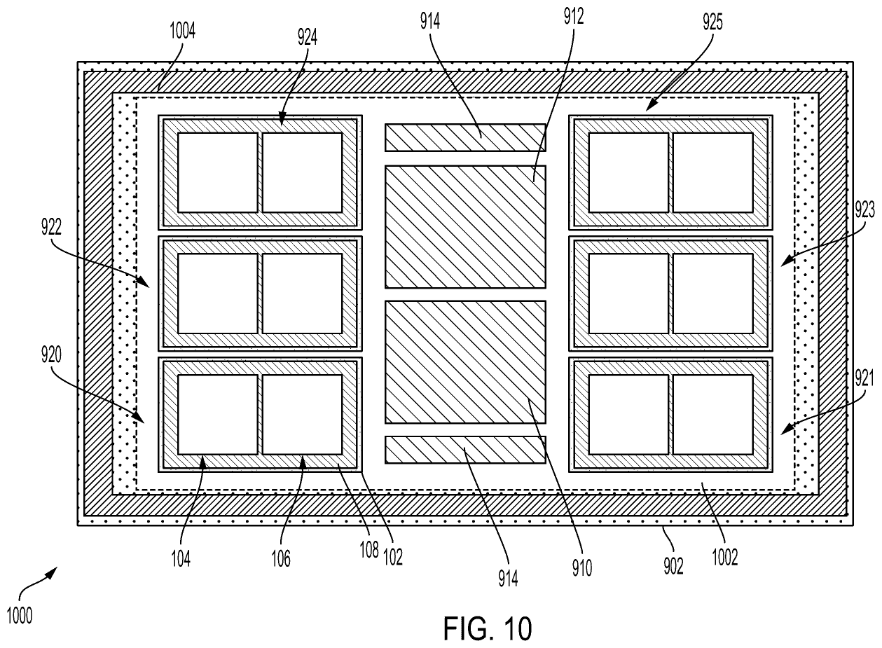

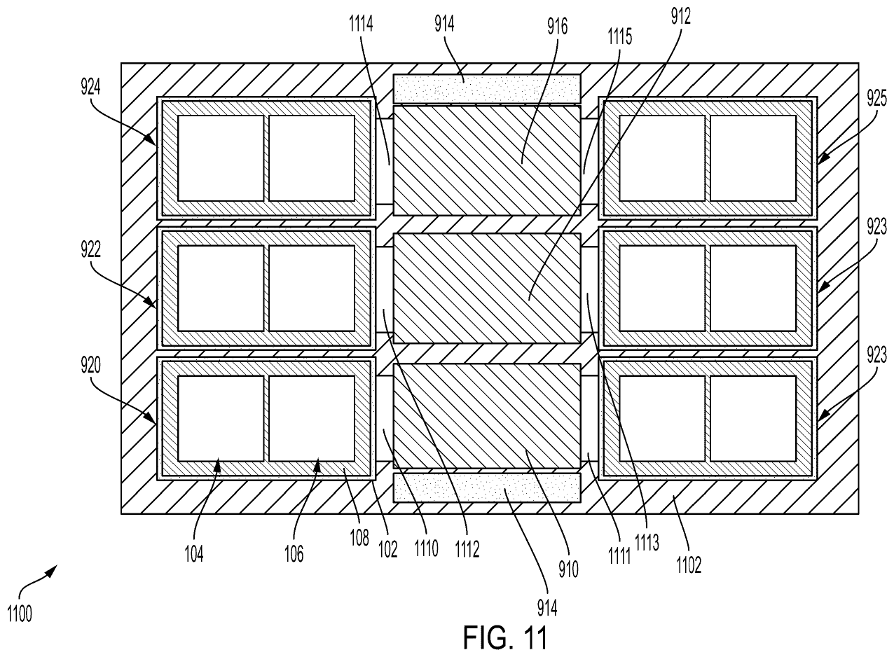

FIG. 10 depicts an exemplary embodiment of a second packaging structure 1000 using the interposer 1002 on the supporting substrate 902. In FIG. 10, unlike FIG. 9, the device package 100 and other elements may be mounted on the interposer 1002, which is itself mounted on the supporting substrate 902. The second packaging structure 1000 of FIG. 10 may include the elements of the first packaging structure 900 of FIG. 9 as otherwise discussed above. In some embodiments, the interposer 1002 may be made of silicon, while in other embodiments another form of semiconductor such as germanium may be used. In some embodiments, multiple interposer substrates may be shared on a single supporting substrate. In some embodiments, the supporting substrate 902 may have the interposer 1002 mounted thereon in a variety of ways and may include pads, bumps, microbumps, pillars, balls, and other forms such as C4 bumps, alone or in combination. In FIG. 10, the plurality of device packages may connect via the interposer 1002 to the one or more compute devices and the connectivity chiplet 914.

The interposer 1002 may contain additional devices in addition to or in alternative to the compute devices and the multi-device packages. Additionally, a stiffener 1004 is shown surrounding a perimeter on the supporting substrate 902. The stiffener 1004 may be one or more sections of a stiff material to provide additional mechanical support to the supporting substrate 902. The stiffener 1004 may be made of a material that has a higher elastic modulus than the elastic modulus of the supporting substrate 902, and thus may include materials such as a metal (e.g., aluminum, copper, or steel), a ceramic, a composite material, or another appropriate material. The stiffener 1004 may be used in combination with a lid design to provide additional protection for the second packaging structure 1000, including protection from mechanical distortions, deformations, and warping. In some embodiments, a lid may be used to provide additional mechanical, thermal, and electrical protection for the second package structure 1000. In some embodiments, a lidless design may be used instead.

Additionally, the stiffener 1004 may be formed directly upon the supporting substrate 902, such as by additive manufacturing of a suitable material to provide additional stiffness to the supporting substrate 902, or may be formed separately and mounted on the supporting substrate 902 using either a bonding process, or an adhesive such as an epoxy or resin. In some embodiments, an additional layer of molding material or encapsulation materials may be deposited between the interposer 1002 and the stiffener 1004. In some embodiments, a lid may be further mounted on to the second package structure 1000 and be attached to the stiffener 1004.

FIG. 11 depicts an exemplary embodiment of a third packaging structure 1100 using an embedded bridge structure. Unlike FIG. 9 and FIG. 10, the third packaging structure 1100 uses one or more embedded bridges within an overmolding layer 1102. The third packaging structure 1100 of FIG. 11 may otherwise include the elements of the second packaging structure 1000 of FIG. 10 and the elements of the first packaging structure 900 of FIG. 9 as otherwise discussed above In FIG. 11, the plurality of device packages may connect via the supporting substrate to the one or more compute devices via individual embedded bridges. The first embedded bridge 1110 may connect the first device package 920 to the first compute device 910 on a first side, along with a second embedded bridge 1111 connecting the second device package 921 to the first compute device 910 on a second side opposite the first side. A third embedded bridge 1112 may connect the third device package 922 to the second compute device 912 on the first side, while a fourth embedded bridge 1113 may connect the fourth device package 923 to the second compute device 912 on the second side. A fifth embedded bridge 1114 may connect the fifth device package 924 to the third compute device 916 on the first side, while a sixth embedded bridge 1115 may connect the sixth device package 925 to the third compute device 916 on the second side.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a first layer including a first device region and a second device region; and
a second layer including an interconnection die, the interconnection die including an interface logic;
wherein the first device region and the second device region are mounted on a first side of the interconnection die; and
wherein the first device region and the second device region are communicatively coupled to the interface logic.

2. The device of claim 1, wherein the first device region includes at least one component device selected from the group consisting of a memory device and a processing device; and
wherein the second device region includes at least one component device selected from the group consisting of a memory device and a processing device.

3. The device of claim 1, wherein the first device region includes a first device and a second device, the first device selected from the group consisting of a memory device and a processing device, and the second device selected from the group consisting of a memory device and a processing device.

4. The device of claim 1, wherein the first device region and the second device region are the same in device composition.

5. The device of claim 1, wherein the first device region and the second device region differ in device composition.

6. The device of claim 1, wherein the interface logic comprises a serial interface logic or a parallel interface logic; and
wherein the interface logic is arranged between the first device region and the second device region.

7. The device of claim 1, wherein the interconnection die has an interconnection region on a second side of the interconnection die, the second side of the interconnection die opposite the first side of the interconnection die; and
wherein the interconnection region is selected from the group consisting of pillars, bumps, and pads.

8. The device of claim 7, wherein the interconnection region is communicatively coupled to the first device region and the second device region.

9. The device of claim 1, wherein the interface logic comprises a serial interface logic or a parallel interface logic; and
wherein the interface logic is mounted on a first side of the first device region and the second device region is mounted on a second side of the first device region, and wherein the second side opposite the first side.

10. A system comprising:
a first layer including a first device stack, and a second device stack, wherein the first device stack is formed in a first device region, and the second device stack is formed in a second device region; and
a second layer including an interconnection die and an interface logic,
wherein the first layer is mounted on top of the second layer.

11. The system of claim 10, wherein
the first device stack is connected by a first through via,
wherein the second device stack is connected by a second through via, and
wherein the first though via and the second though via are communicatively coupled to the interface logic.

12. The system of claim 10, wherein the first device stack has the same device composition as the second device stack.

13. The system of claim 10, wherein the first device stack is different from the second device stack.

14. The system of claim 10, wherein
the interface logic is arranged between the first device stack and the second device stack, and
wherein the interface logic is a serial logic.

15. The system of claim 10, wherein
the interface logic is arranged on a first side of the first device stack, and the second device stack is arranged on a second side of the first device stack, the second side opposite the first side, and
the interface logic is a parallel logic.

16. A method comprising:
forming an interconnection die including an embedded interface logic, and forming a wiring layer, the wiring layer communicatively coupled to the embedded interface logic;
mounting a first device and a second device on the interconnection die, the first device and the second device communicatively coupled to the wiring layer;
mounting additional first devices on the first device to form a first device region;
mounting additional second devices on the second devices to form a second device region;
wherein the additional first devices are communicatively coupled to the first device;
wherein the additional second devices are communicatively coupled to the second device; and
forming a molding layer over the interconnection die, the first device region, and the second device region.

17. The method of claim 16, wherein the first device region and the second device region have the same device composition.

18. The method of claim 16, wherein the device composition of the first device region is different from the second device region.

19. The method of claim 16, wherein mounting the first device and the second device on the interconnection die includes mounting the first device on a first side of the embedded interface logic and mounting the second device on a second side of the embedded interface logic, wherein the second side is opposite the first side.

20. The method of claim 16, wherein mounting the first device and the second device on the interconnection die includes mounting the second device on a first side of the first device and mounting the first device so the embedded interface logic is on a second side of the first device, wherein the second side is opposite the first side.
